(19) United States
(12) Patent Application Publication
(10) Pub. No.: US 2023/0394182 A1
(43) Pub. Date: Dec. 7, 2023

(54) Modeling Adjustments Using Recursion

(71) Applicant: New COS Inc., Cleveland, OH (US)

(72) Inventors: Kevin Libertowski, Cleveland, OH (US); Brian Beckrest, Lakewood, OH (US); Keith Grafmeyer, Cleveland, OH (US)

(21) Appl. No.: 18/204,924

(22) Filed: Jun. 1, 2023

Related U.S. Application Data
(60) Provisional application No. 63/396,934, filed on Aug. 10, 2022.
(60) Provisional application No. 63/396,932, filed on Aug. 10, 2022.
(60) Provisional application No. 63/348,306, filed on Jun. 2, 2022.
(60) Provisional application No. 63/348,304, filed on Jun. 2, 2022.
(60) Provisional application No. 63/348,299, filed on Jun. 2, 2022.
(60) Provisional application No. 63/348,316, filed on Jun. 2, 2022.
(60) Provisional application No. 63/347,916, filed on Jun. 1, 2022.

(51) Int. Cl. G06F 30/10; G06T 7/12; G06T 7/60

(52) U.S. Cl. CPC G06F 30/10; G06T 7/12; G06T 7/60; G06T 2200/24

(57) ABSTRACT

A stent design system has a memory device to store a set of instructions which, when executed by a processing device, determine a lumen cross-section of a lumen model. The stent design system determines a center point of the lumen cross-section. The stent design system determines a plurality of surface points of a surface of the lumen cross-section. The stent design system determines an updated center point using a centroid of the plurality of surface points.

### PRIORITY

This patent application claims priority from provisional U.S. patent application Ser. No. 63/347,916 (filed Jun. 1, 2022), 63/348,316 (filed Jun. 2, 2022), 63/348,299 (filed Jun. 2, 2022), 63/348,304 (filed Jun. 2, 2022), 63/348,306 (filed Jun. 2, 2022), 63/396,932 (filed Aug. 10, 2022), 63/396,934 (filed Aug. 10, 2022) the disclosures of which are incorporated herein, in its entirety, by reference.

### FIELD

This invention relates to stent design and, more particularly, to 3D modeling tools, systems, and software for designing stents.

### BACKGROUND

Accurate representations of anatomical structures may allow for customization in medical treatment. For example, inner cavities of anatomical tubular structures, also known as lumens, are present in humans and other organisms. Lumens may be hollow, such as airways, or filled with another substance such a blood vessel filled with blood or a bone filled with bone marrow. Changes in an anatomical lumen may require medical intervention. For example, when an airway narrows or closes, a medical professional may insert a stent into the lumen to correct a medical condition. Since anatomical lumens have non-uniform shapes and sizes, a customized medical device (e.g., a stent) to correct a lumen-based medical condition would enhance medical treatment.

### SUMMARY OF VARIOUS EMBODIMENTS

In accordance with one embodiment of the invention, a stent design system has a memory device to store a set of instructions which, when executed by a processing device, determine a lumen cross-section of a lumen model. The stent design system determines a center point of the lumen cross-section. The stent design system determines surface points of a surface of the lumen cross-section. The stent design system determines an updated center point using a centroid of the surface points.

Determining the surface points of the lumen cross-section may use the center point.

Determining the surface points may include casting rays between a surface of the lumen model and the center point.

In some embodiments, the stent design system determines a cross-section guideline of a lumen model. Determining the lumen cross-section may include determining a plane perpendicular to the guideline.

In some embodiments, the stent design system determines a distance between the center point and the updated center point, and determines a final center point after determining the distance between the center point and the updated center point.

In some embodiments, the stent design system determines centroid-based center points for a lumen cross-sections and determines a centerline for the lumen model using the centroid-based center points.

In some embodiments, the stent design system determines branching region edges using the cross-sections and the centroid-based center points. In accordance with another embodiment, a method for designing a stent determines a lumen cross-section of a lumen model. The method determines a center point of the lumen cross-section. The method determines a surface points of a surface of the lumen cross-section. The method determines an updated center point using a centroid of the surface points.

Determining the surface points of the lumen cross-section may use the center point. Determining the surface points may include casting rays between a surface of the lumen model and the center point.

In some embodiments, the method determines a cross-section guideline of a lumen model. Determining the lumen cross-section includes determining a plane perpendicular to the guideline.

In some embodiments, the method determines a distance between the center point and the updated center point. The method may also determine a final center point after determining the distance between the center point and the updated center point.

In some embodiments, the method determines centroid-based center points for a lumen cross-sections, and determines a centerline for the lumen model using the centroid-based center points.

In some embodiments, the method determines a branching region edges using the cross-sections and the centroid-based center points.

Illustrative embodiments of the invention are implemented as a computer program product having a computer usable medium with computer readable program code thereon. The computer readable code may be read and utilized by a computer system in accordance with conventional processes.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1 schematically shows inputs and outputs of a stent design system in accordance with various embodiments.

FIG. 2 is a flowchart showing a recursive centerline adjustment process for determining the centerline of a lumen in accordance with various embodiments.

FIGS. 3A-3B illustrate center point adjustments during the process of FIG. 2 in accordance with various embodiments.

FIG. 4 is a flowchart showing a process for determining branching regions in accordance with various embodiments.

FIG. 5 shows a 3D lumen model with a centerline and branching region in accordance with various embodiments.

FIG. 6 is a flowchart showing a machine learning-based centerline determination process in accordance with various embodiments.

FIG. 7 schematically shows a neural network for finding a centerline in accordance with various embodiments.

FIG. 8 shows rays cast from a voxel during the process of FIG. 6 in accordance with various embodiments.

FIGS. 9A-9B illustrates results of two iterations of the process of FIG. 6 in accordance with various embodiments.

FIG. 10 schematically shows a block diagram of a computing device in accordance with various embodiments.

### DESCRIPTION OF ILLUSTRATIVE EMBODIMENTS

In illustrative embodiments, a stent design system is configured to generate a 3D model of an anatomical tubular structure including a lumen. The stent design system may use machine learning and/or a recursive center point adjustment process to determine center points or centerlines of lumen cross-sections. The stent design system may provide a user interface for designing a stent or other medical device to be inserted into the lumen. The user interface may display multiple views, such as perspective views of the 3D model, cross-sectional views of the 3D model, or 2D CT scan images with stent design overlays. Using the user interface, the user may place multiple objects, such as a sphere, that correspond to the size (e.g., diameter) and position of a desired stent. The stent design system may automatically position the objects at a center point of the lumen or along centerlines of the lumen cross-sections, as indicated by the user. The stent design system may also automatically size the objects based on the diameter of the lumen at the cross-section where the center point is located. The stent design system may use the sizing and location of the objects to generate a customized stent model. Generating a stent model based on selected locations and diameters may be performed by a number of methods, such as the methods described in International Publication No. 2021/007570 entitled “System And Method For Model-Based Stent Design And Placement.” Details of illustrative embodiments are discussed below.

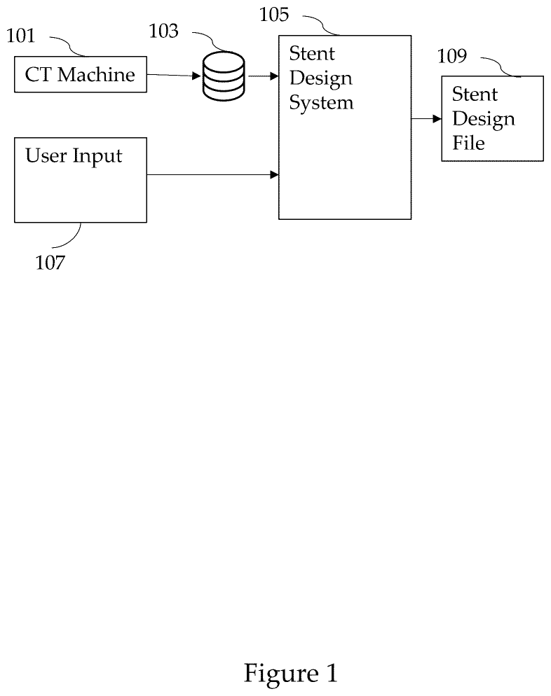

FIG. 1 schematically shows a stent design system 105, also known as a medical device design system, configured, among other things, to design a customized stent to expand or open a lumen, or to design a medical device. Embodiments below illustrate stent design for a human airway. Other embodiments may include stents designed for animals, or stents designed for other anatomical lumens, such as vascular stents, colonic stents, biliary stents, ureteral stents, or esophageal stents, among other things. Anatomical lumens may also include bones having an inner cavity of bone marrow, and the stent design system 105 may be configured to design a medical device to be inserted into the marrow cavity of the bone. For example, the medical device may include a stem of an implant inserted into the bone for joint replacement. It should be appreciated that anatomical lumens are not perfectly circular, or non-circular.

The stent design system 105 is configured to receive 2D anatomical images from a data structure 103. The 2D anatomical images may be generated by a computer tomography (CT) machine 101, or another imaging system. The stent design system 105 is also configured to receive a user input 107 from a user. The user input 107 may be configured to adjust an anatomical model, a centerline, or a stent model, among other things. The stent design system 105 is configured to output a stent design, such as in the form of a stent design file 109.

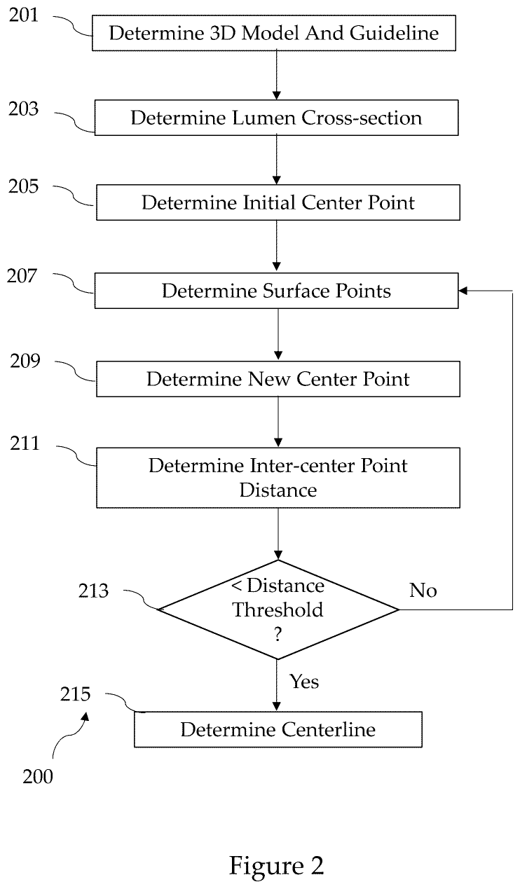

FIG. 2 shows a recursive center point adjustment process 200 configured to determine a center point of a lumen cross-section. The process 200 may be implemented in whole or in part in one or more of the stent design systems disclosed herein. It shall be further appreciated that a number of variations and modifications to the process 200 are contemplated including, for example, the omission of one or more aspects of the process 200, the addition of further conditionals and operations and/or the reorganization or separation of operations and conditionals into separate processes.

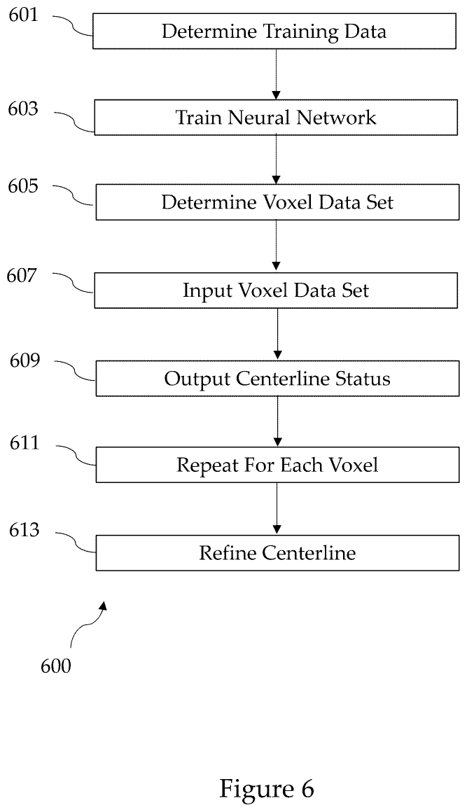

The process 200 begins at operation 201 where the stent design system determines a 3D model (or 3D mesh) of a lumen and a cross-sectional guideline. Determining the 3D model may include receiving the 3D model or generating the 3D model based on 2D images, such as CT scan images, among other things. Determining the cross-sectional guideline may include receiving the guideline or generating the guideline based on the 3D model. In some embodiments, the guideline is the centerline derived from the process 600 in FIG. 6. The cross-sectional guideline is positioned within the modeled lumen and perpendicular to preferred cross-sections of the 3D model. Preferred cross-sections may include cross-sections in stentable areas of the lumen, or cross-sections that are perpendicular to the lumen. For example, the stentable region of a human airway may extend to the lobes of the lungs. In some embodiments, the cross-sectional guideline is an estimated centerline; however, the cross-sectional guideline does not need to be an estimated centerline for the purposes of the process 200.

The process 200 proceeds to operation 203 where the stent design system determines a cross-section of the lumen using the cross-sectional guideline. The cross-sectional guideline may be configured to be perpendicular to preferred cross-sections of the modeled lumen down its entire length. Therefore, the stent design system determines a cross-section of the lumen by determining a plane perpendicular to the cross-sectional guideline. In certain embodiments, the stent design system may determine perpendicularity based on an averaged rate of change of the cross-sectional guideline.

The process 200 proceeds to operation 205 where the stent design system determines an initial center point. For example, the stent design system may use the cross-section guideline and the cross-section. The initial center point may be the place where the plane of the cross-section intersects with the cross-sectional guideline. In other embodiments, the user may select or adjust the initial center point before the process 200 proceeds to operation 207.

The process 200 proceeds to operation 207 where the stent design system determines points along the outer surface of the lumen using the initial center point. Determining the lumen outer surface points may include casting rays from the initial center point to the outer surface of the lumen within the cross-section in a circular or radial pattern. The points at which the rays intersect with the outer surface of the lumen may be the lumen outer surface points. Among other things, the number of rays may be such that the lumen outer surface points are spaced 1-1.25 mm apart when casting the largest cross-sections of an airway. Among other things, the number of rays may be based on the voxel size of the 3D model. Among other things, the voxels of the 3D model may include a range inclusive of about 0.7×0.7×0.5 mm and 1×1×1.5 mm, or a voxel size of about 1×1×1.25 mm. The number of rays cast may correspond to the spacing between lumen outer surface points being approximately a voxel size of the 3D model. By using points along the outer surface of the lumen rather than ray casting equal-length rays, the process 200 is able to determine a center point of a wide range of non-circular cross-sections.

The process 200 proceeds to operation 209 where the stent design system determines a new center point using the lumen outer surface points. The new center point may be the centroid of the lumen outer surface points. For example, the stent design system may use the following formula to determine the new center point, where N is the total number of points and Pᵢ is the i-th lumen surface point and is located at coordinates x, y, and z:

$$\frac{{\sum }_{i = 1}^{N} {P}_{{i}_{x , y , z}}}{N} \qquad ( 1 )$$

The process 200 then proceeds to operation 211 where the stent design system determines an inter-center point distance between the two most recent center points. At conditional 213, the inter-center point distance is compared to a distance threshold. If the inter-center point distance is greater than the distance threshold, the process 200 returns to operation 207 and repeats operations 207-213 until the inter-center point distance becomes less than the distance threshold. When the inter-center point distance is less than the distance threshold, the process 200 proceeds to operation 215, where the process 200 determines a centerline using the new center point. Among other things, determining a centerline may include repeating operations 203—conditional 213 until the process determines center points for multiple cross sections. The determined center points may then be connected to form a centerline.

It should be appreciated that the process 200 may be used to determine a single center point, or may be repeated at regular intervals along the cross-sectional guideline to generate a centroid-based centerline for the 3D lumen model. Among other things, the process 200 may be repeated every millimeter along the cross-sectional guideline to generate a centroid-based centerline. Instead of every millimeter, the process 200 may be repeated for another sampling distance determined by the spatial resolution of the 2D image upon which the 3D lumen model is based. For example, if the slice thickness of a CT scan is 1.25 mm, then the sampling distance may be less than 1.25 mm to prevent aliasing.

In certain embodiments, the 3D lumen model used by the process 200 may be first filtered or smoothed. For example, the 3D lumen model may include an initial set of raw voxels that makeup a corresponding airway. After initially skeletonizing the voxels (using a marching cubes algorithm), the model may have rough edges due to the relatively low resolution of the CT image scans. To fix this problem, the 3D model, or mesh, is run through a smoothing algorithm.

By doing this smoothing, the process 200 may find a more accurate centerline than if the voxels that make up the cross-section were averaged.

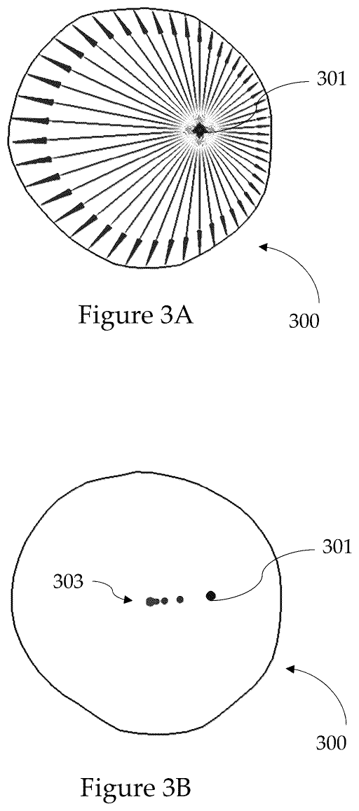

FIGS. 3A-3B illustrates operations of the process 200 in accordance with various embodiments. FIG. 3A shows rays being cast from an initial center point 301 in a circular pattern, which may be performed in operation 207 of the process 200. FIG. 3B shows the initial center point 301, as well as the center points determined during the iterations of operations 207-213 of the process 200, including a final center point 303. The inter-center point distances decrease for each iteration of operations 207-213 until the distance between the final center point 303 and the previous center point is less than the distance threshold.

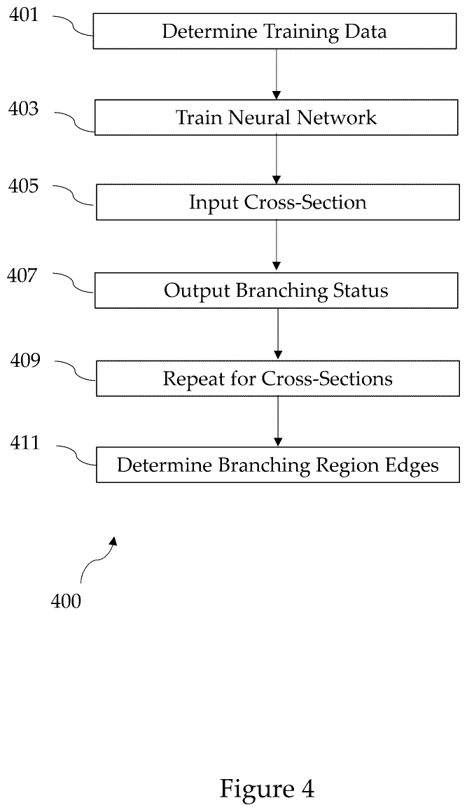

FIG. 4 is a flowchart showing a branching region identification process 400 in accordance with various embodiments. For branching lumens, identifying the branching region of a lumen model is critical to properly position the centerline of the model. An incorrect centerline may cause an ill-fitting stent where the stent is to be placed in a branching region, such as a carinal region of an airway. The process 400 may be implemented in whole or in part in one or more of the stent design systems disclosed herein. It shall be further appreciated that a number of variations and modifications to the process 400 are contemplated including, for example, the omission of one or more aspects of the process 400, the addition of further conditionals and operations and/or the reorganization or separation of operations and conditionals into separate processes.

The process 400 begins at operation 401 by determining the training data to be used for training the neural network. The training data may include labeled data. For example, the training data may have representations of lumen cross-sections with center points labeled as being a branching region edge or a non-branching region edge. The cross-sections may be generated using the process 200, the process 600, or a combination thereof, among other things. In some embodiments, the training data may be labeled as being within a branching region or outside of a branching region. The process 400 may determine the training data by labeling data or accessing stored, pre-labeled training data. In some embodiments, the training data is labeled manually by a user analyzing each cross-section representation of the training data.

The process 400 proceeds to operation 403 by training the neural network to determine a branching status based on a provided lumen cross section. Training the neural network may include selecting a number of inputs in the input layer, a number of outputs in the output layer, and a number of hidden layers, as well as a number of nodes in the hidden layers. The output of the neural network is configured to output an indication of whether the cross-section is a branching region edge. The indication may be a classification or a probability, among other things.

The process 400 proceeds to operation 405 by inputting a representation of a cross-section of a lumen with a center point into the neural network. In some embodiments, inputting the representation of the lumen cross-section may include dividing the representation into subsections, such as pixels or voxels, and apply pre-processing filters before providing the representation to the input layer of the neural network.

In some embodiments, the representation of the cross-section of the lumen may include the location of points along the surface of the lumen, which may be represented by a distance between the point and the center point. The representations may also include a normalized version of the distance. For example, the distances may be normalized on a scale between 0 and 1. In some embodiments, the representation of the cross-section of the lumen may include a section identifier which indicates a section of the lumen model where the cross-section may be found. For example, an airway may be partitioned into 23 generations of branching, extending from the trachea (generation 0) the last order of the terminal bronchioles. At each generation, the airway is being divided into two smaller child airway branches. The section identifier would then indicate which generation includes the cross-section.

The process 400 proceeds to operation 407 by outputting a branching status for the lumen cross-section. The branching status may be a probability the cross-section is a branching region edge or a probability the cross-section is within the branching region of the lumen, among other things.

After completing operations 405 and 407 for one cross-section representation, operation 409 includes repeating operations 405 and 407 for a set of cross-section representations of the same lumen in order to determine branching statuses for each cross-section.

Once the neural network has output a set of branching statuses, the process 400 proceeds to operation 411 by determining the branching region edges using the branching statuses. In some embodiments, where the branching statuses include a probability, the operation 411 may include comparing each probability to each other or to a threshold to determine which cross-section is the edge of the branching region. For example, the operation 411 may determine the branching region edge by selecting the cross-section with the highest probability determined by the neural network. In another example, the operation 411 may determine the branching region edge by comparing the probabilities and selecting the cross-section with the largest change in probability compared to an adjacent cross-section, in addition to or in place of having a probability above a threshold.

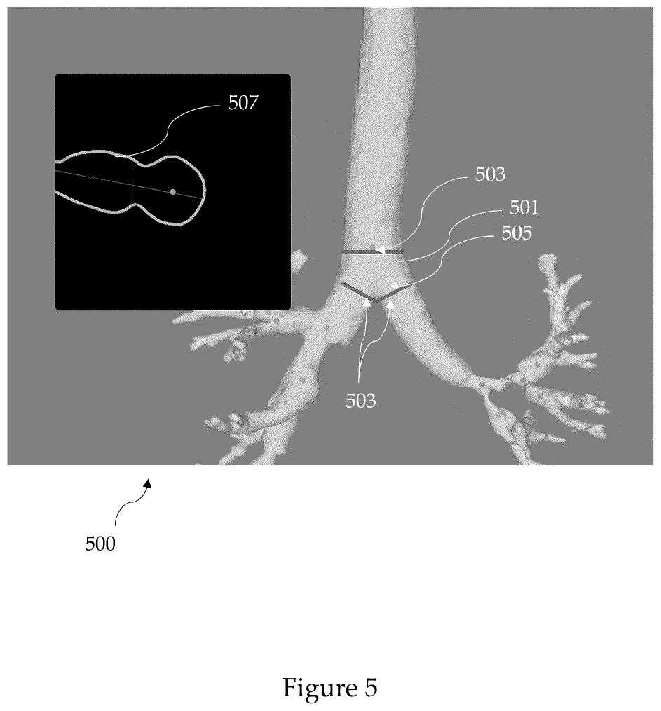

FIG. 5 shows a user interface 500 displaying a 3D lumen model having a carinal region 501 where branches of the airway are joined together in accordance with various embodiments. The carinal region 501 is defined by carinal region edges 503 identified by the process 400. Outside of the carinal region 501, lumen cross-sections may appear tubular such as the lumen illustrated in FIGS. 3A and 3B. Within the carinal region, cross-sections indicate a branching region. For example, the cross-section 507, displayed on user interface 500, representing the cross section at point 505 of the centerline within the cranial branching region, resembles a fusion of two tubular structures, indicating there is a high probability the cross-section at point 505 is in the carinal region.

As shown, the modeled lumen may have a branching structure, such as an airway. Similarly, the centerline also has a branching structure such that the centerline has a tree structure.

FIG. 6 is a flowchart showing a machine learning-based centerline determination the process 600 in accordance with various embodiments. In some embodiments, the process 600 determines a centerline which may be used as a guideline in the process 200 in FIG. 2. The process 600 may be implemented in whole or in part in one or more of the stent design systems disclosed herein. It shall be further appreciated that a number of variations and modifications to the process 600 are contemplated including, for example, the omission of one or more aspects of the process 600, the addition of further conditionals and operations and/or the reorganization or separation of operations and conditionals into separate processes.

The process 600 begins at operation 601 where the stent design system determines training data for generating a neural network. The stent design system may also determine testing or validation data for generating the neural network. In some embodiments, the training data includes 3D lumen models with centerlines determined by the recursive center point adjustment process of FIG. 2. The centerlines determined by the recursive center point adjustment process may be partially adjusted by a user before the stent design system uses the training data in operation 603.

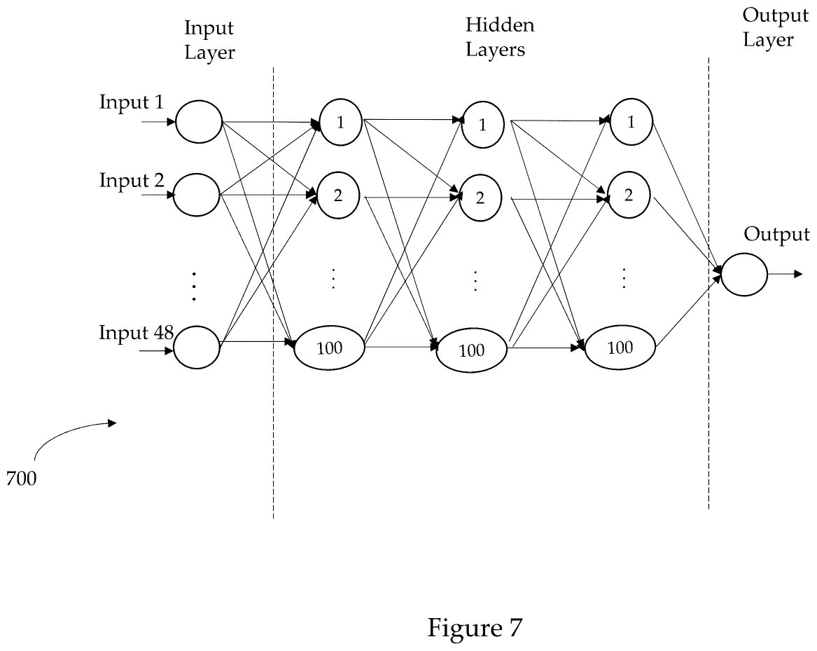

The process 600 proceeds to operation 603, where the stent design system trains a neural network using the training, testing, and/or validation data from operation 601. FIG. 7 schematically shows a neural network 700 in accordance with various embodiments. The neural network 700 is a multi-layer perceptron neural network having an input layer with 48 inputs, three hidden fully connected layers each having a size of 100 nodes, and an output layer having a single classification output. The 48 inputs include: a centricity value, a mean radius of the casted rays, a minimum radius of the casted rays, position coordinates (x, y, or z coordinate) of the voxel, and ray length values for each of 42 casted rays. The nodes of the hidden layers may include rectified linear activation units (ReLU). The output layer may include a sigmoid activation function to classify a voxel as a centerline voxel (output above 0.5) or non-centerline voxel.

With continuing reference to FIG. 6, operation 603 may generate neural networks different than that of neural network 700 in FIG. 7. Among other things, embodiments may include a different type of neural network, more or fewer hidden layers, or more or fewer inputs to the input layer.

The process 600 proceeds to operation 605 where the stent design system determines, for one voxel, a voxel data set configured to be input into the neural network. The stent design system may determine the voxel data set by casting rays from one voxel of the 3D model to points on the outer surface of the modeled lumen. In some embodiments, the number of casted rays is at least 42 rays for the voxel. The voxel data set input into the neural network may include one or more of the following items, which may be determined using the casted rays: a centricity value, a mean radius of the casted rays, a minimum radius of the casted rays, position coordinates (x, y, or z coordinate), or ray length values for each casted ray. The voxel data set may also include a voxel density or a number of neighboring voxels. In some embodiments, the stent design system may apply a Gaussian blur filter to the voxels of the 3D model to smooth the 3D model before casting the rays to determine the voxel data set.

The process 600 proceeds to operation 607 where the voxel data set is input into the neural network. The process 600 proceeds to operation 609 where the neural network outputs centerline status for the voxel. The centerline status may be a classification of the voxel. For example, the centerline status may indicate whether the voxel is a centerline voxel. The centerline status may also be a probability that the voxel is a centerline voxel.

The process 600 proceeds to operation 611 where operations 605 to 609 are repeated for each voxel of the interior of the lumen. After the neural network outputs centerline status for each voxel, the voxels indicated by the neural network as being centerlines may be grouped together. In another embodiment, voxels may be grouped together based on a probability of the centerline status. For example, voxels with a high probability of being centerline voxels may be grouped together. The process 600 proceeds to operation 613, where operations 605 through 611 are repeated for the group of centerline voxels. Operation 613 may be repeated until the group of centerline voxels forms a centerline less than a thickness threshold. After operation 613, the final centerline may be post-processed. Among other things, the final centerline may be smoothed or invalid branches of the centerline may be removed.

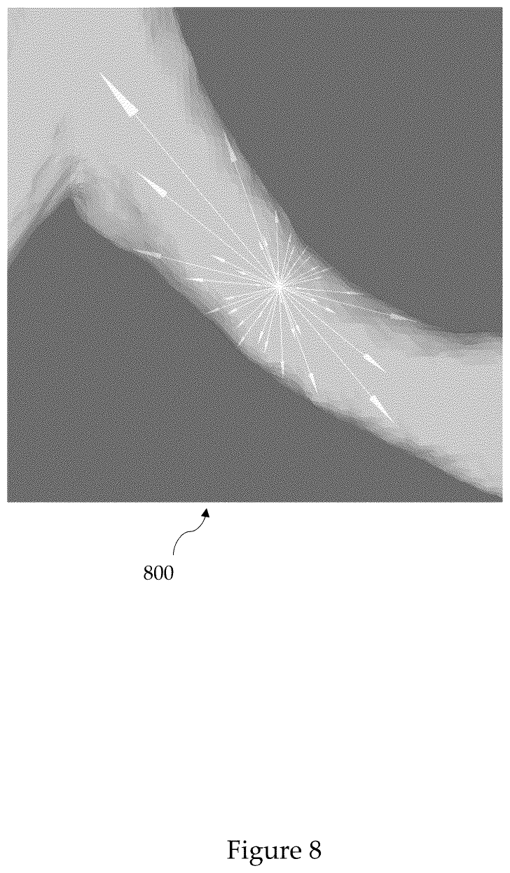

FIG. 8 shows rays 800 cast within a lumen from a voxel during the process of FIG. 6 in accordance with various embodiments. Unlike the recursive center point adjustment process of FIG. 2, the casted rays of the machine learning-based centerline determination process in FIG. 6 are not confined to a cross-section. Instead, the stent design system 105 casts rays in three dimensions.

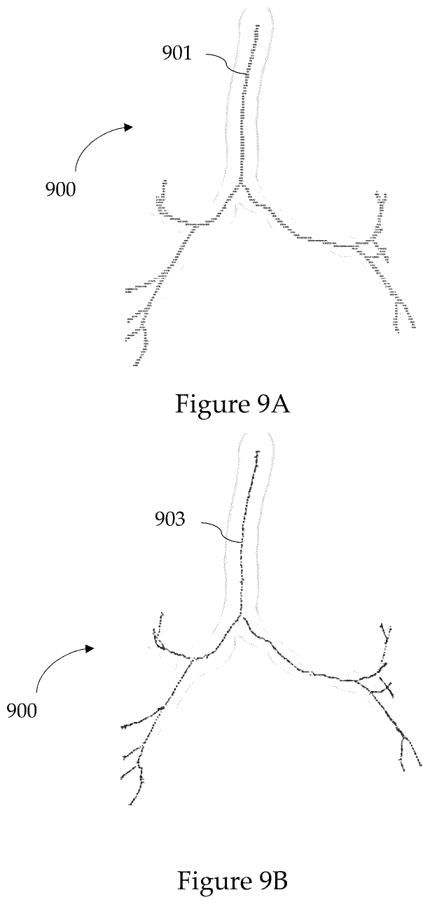

FIGS. 9A-9B show exemplary centerline iterations of the machine learning-based centerline determination process of FIG. 6 in accordance with various embodiments. The centerline of FIG. 9A corresponds to an earlier iteration where the thickness of the centerline formed by the group of centerline voxels exceeds a thickness threshold. The centerline of FIG. 9B corresponds to a later iteration after a previous group of centerline voxels is fed into the neural network.

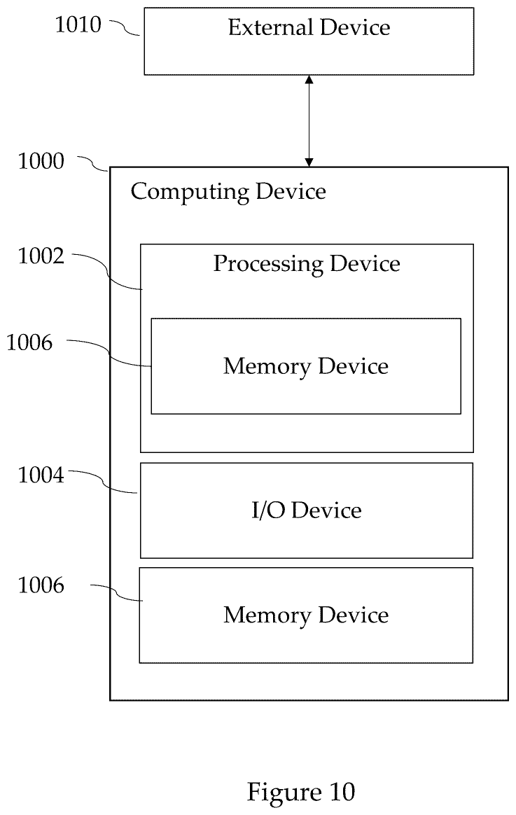

FIG. 10 schematically shows a computing device 1000 in accordance with various embodiments. Computing device 1000 is one example of a stent design system 105 shown in FIG. 1. Computing device 1000 includes a processing device 1002, an input/output device 1004, and a memory device 1006. Computing device 1000 may be a stand-alone device, an embedded system, or a plurality of devices configured to perform the functions described with respect to stent design system 105. Furthermore, computing device 1000 may communicate with one or more external devices 1010.

Input/output device 1004 enables computing device 1000 to communicate with external device 1010. For example, input/output device 1004 in different embodiments may be a network adapter, network credential, interface, or a port (e.g., a USB port, serial port, parallel port, an analog port, a digital port, VGA, DVI, HDMI, FireWire, CAT 5, Ethernet, fiber, or any other type of port or interface), to name but a few examples. Input/output device 1004 may be comprised of hardware, software, or firmware. It is contemplated that input/output device 1004 includes more than one of these adapters, credentials, or ports, such as a first port for receiving data and a second port for transmitting data.

External device 1010 in different embodiments may be any type of device that allows data to be input to or output from computing device 1000. For example, external device 1010 in different embodiments is a mobile device, a reader device, equipment, a handheld computer, a diagnostic tool, a controller, a computer, a server, a printer, a display, an alarm, a visual indicator, a keyboard, a mouse, a user device, a cloud device, a circuit, or a touch screen display. Furthermore, it is contemplated that external device 1010 is be integrated into computing device 1000. It is further contemplated that more than one external device is in communication with computing device 1000.

Processing device 1002 in different embodiments is a programmable type, a dedicated, hardwired state machine, or a combination thereof. Device 1002 may further include multiple processors, Arithmetic-Logic Units (ALUs), Central Processing Units (CPUs), Digital Signal Processors (DSPs), or Field-programmable Gate Array (FPGA), to name but a few examples. For forms of processing device 1002 with multiple processing units, distributed, pipelined, or parallel processing may be used as appropriate. Processing device 1002 may be dedicated to performance of just the operations described herein or may be utilized in one or more additional applications. In the illustrated form, processing device 1002 is of a programmable variety that executes processes and processes data in accordance with programming instructions (such as software or firmware) stored in memory device 1006. Alternatively or additionally, programming instructions may be at least partially defined by hardwired logic or other hardware. Processing device 1002 may be comprised of one or more components of any type suitable to process the signals received from input/output device 1004 or elsewhere, and provide desired output signals. Such components may include digital circuitry, analog circuitry, or a combination of both.

Memory device 1006 in different embodiments is of one or more types, such as a solid-state variety, electromagnetic variety, optical variety, or a combination of these forms, to name but a few examples. Furthermore, memory device 1006 may be volatile, nonvolatile, transitory, non-transitory or a combination of these types, and some or all of memory device 1006 may be of a portable variety, such as a disk, tape, memory stick, cartridge, to name but a few examples. In addition, memory device 1006 may store data that is manipulated by processing device 1002, such as data representative of signals received from or sent to input/output device 1004 in addition to or in lieu of storing programming instructions, to name but a few examples. As shown in FIG. 10, memory device 1006 may be included with processing device 1002 or coupled to processing device 1002, but need not be included with both.

It is contemplated that the various aspects, features, processes, and operations from the various embodiments may be used in any of the other embodiments unless expressly stated to the contrary. Certain operations illustrated may be implemented by a computer executing a computer program product on a non-transient, computer-readable storage medium, where the computer program product includes instructions causing the computer to execute one or more of the operations, or to issue commands to other devices to execute one or more operations.

While the present disclosure has been illustrated and described in detail in the drawings and foregoing description, the same is to be considered as illustrative and not restrictive in character, it being understood that only certain exemplary embodiments have been shown and described, and that all changes and modifications that come within the spirit of the present disclosure are desired to be protected. It should be understood that while the use of words such as “preferable,” “preferably,” “preferred” or “more preferred” utilized in the description above indicate that the feature so described may be more desirable, it nonetheless may not be necessary, and embodiments lacking the same may be contemplated as within the scope of the present disclosure, the scope being defined by the claims that follow. In reading the claims, it is intended that when words such as “a,” “an,” “at least one,” or “at least one portion” are used there is no intention to limit the claim to only one item unless specifically stated to the contrary in the claim. The term “of” may connote an association with, or a connection to, another item, as well as a belonging to, or a connection with, the other item as informed by the context in which it is used. The terms “coupled to,” “coupled with” and the like include indirect connection and coupling, and further include but do not require a direct coupling or connection unless expressly indicated to the contrary. When the language “at least a portion” or “a portion” is used, the item can include a portion or the entire item unless specifically stated to the contrary. Unless stated explicitly to the contrary, the terms “or” and “and/or” in a list of two or more list items may connote an individual list item, or a combination of list items. Unless stated explicitly to the contrary, the transitional term “having” is open-ended terminology, bearing the same meaning as the transitional term “comprising.”

Various embodiments of the invention may be implemented at least in part in any conventional computer programming language. For example, some embodiments may be implemented in a procedural programming language (e.g., “C”), or in an object oriented programming language (e.g., “C++”). Other embodiments of the invention may be implemented as a pre-configured, stand-alone hardware element and/or as preprogrammed hardware elements (e.g., application specific integrated circuits, FPGAs, and digital signal processors), or other related components.

In an alternative embodiment, the disclosed apparatus and methods (e.g., see the various flow charts described above) may be implemented as a computer program product for use with a computer system. Such implementation may include a series of computer instructions fixed either on a tangible, non-transitory medium, such as a computer readable medium (e.g., a diskette, CD-ROM, ROM, or fixed disk). The series of computer instructions can embody all or part of the functionality previously described herein with respect to the system.

Those skilled in the art should appreciate that such computer instructions can be written in a number of programming languages for use with many computer architectures or operating systems. Furthermore, such instructions may be stored in any memory device, such as semiconductor, magnetic, optical or other memory devices, and may be transmitted using any communications technology, such as optical, infrared, microwave, or other transmission technologies.

Among other ways, such a computer program product may be distributed as a removable medium with accompanying printed or electronic documentation (e.g., shrink wrapped software), preloaded with a computer system (e.g., on system ROM or fixed disk), or distributed from a server or electronic bulletin board over the network (e.g., the Internet or World Wide Web). In fact, some embodiments may be implemented in a software-as-a-service model (“SAAS”) or cloud computing model. Of course, some embodiments of the invention may be implemented as a combination of both software (e.g., a computer program product) and hardware. Still other embodiments of the invention are implemented as entirely hardware, or entirely software.

The embodiments of the invention described above are intended to be merely exemplary; numerous variations and modifications will be apparent to those skilled in the art. Such variations and modifications are intended to be within the scope of the present invention as defined by any of the appended claims. It shall nevertheless be understood that no limitation of the scope of the present disclosure is hereby created, and that the present disclosure includes and protects such alterations, modifications, and further applications of the exemplary embodiments as would occur to one skilled in the art with the benefit of the present disclosure.

What is claimed is:

1. A stent design system, comprising:
a processing device; and
a memory device configured to store a set of instructions which, when executed by the processing device, is configured to:
determine a lumen cross-section of a lumen model;
determine a center point of the lumen cross-section;
determine a plurality of surface points of a surface of the lumen cross-section; and
determine an updated center point using a centroid of the plurality of surface points.

2. The stent design system of claim 1, wherein determining the plurality of surface points of the lumen cross-section uses the center point.

3. The stent design system of claim 2, wherein determining the plurality of surface points includes casting a plurality of rays between a surface of the lumen model and the center point.

4. The stent design system of claim 1, comprising determining a cross-section guideline of the lumen model, wherein determining the lumen cross-section includes determining a plane perpendicular to a guideline.

5. The stent design system of claim 1, comprising:
determining a distance between the center point and the updated center point; and
determining a final center point after determining the distance between the center point and the updated center point.

6. The stent design system of claim 1, comprising:
determining a plurality of centroid-based center points for a plurality of lumen cross-sections; and
determining a centerline for the lumen model by connecting the plurality of centroid-based center points.

7. The stent design system of claim 6, comprising:
determining a plurality of branching region edges using the plurality of lumen cross-sections and the plurality of centroid-based center points.

8. A method for designing a stent, comprising:
determining a lumen cross-section of a lumen model;
determining a center point of the lumen cross-section;
determining a plurality of surface points of a surface of the lumen cross-section; and
determining an updated center point using a centroid of the plurality of surface points.

9. The method of claim 8, wherein determining the plurality of surface points of the lumen cross-section uses the center point.

10. The method of claim 9, wherein determining the plurality of surface points includes casting a plurality of rays between a surface of the lumen model and the center point.

11. The method of claim 8, comprising determining a cross-section guideline of the lumen model, wherein determining the lumen cross-section includes determining a plane perpendicular to a guideline.

12. The method of claim 8, comprising:
determining a distance between the center point and the updated center point; and
determining a final center point after determining the distance between the center point and the updated center point.

13. The method of claim 8, comprising:
determining a plurality of centroid-based center points for a plurality of lumen cross-sections; and
determining a centerline for the lumen model using the plurality of centroid-based center points.

14. The method of claim 13, comprising:
determining a plurality of branching region edges using the plurality of lumen cross-sections and the plurality of centroid-based center points.

15. A computer program product for use on a computer system for designing a stent, the computer program product comprising a tangible, non-transient computer usable medium having computer readable program code thereon, the computer readable program code comprising:
program code for determining a lumen cross-section of a lumen model;
program code for determining a center point of the lumen cross-section;
program code for determining a plurality of surface points of a surface of the lumen cross-section; and
program code for determining an updated center point using a centroid of the plurality of surface points.

16. The computer program product of claim 15, wherein determining the plurality of surface points of the lumen cross-section uses the center point.

17. The computer program product of claim 16, wherein determining the plurality of surface points includes casting a plurality of rays between a surface of the lumen model and the center point.

18. The computer program product of claim 15, comprising:
program code for determining a cross-section guideline of the lumen model,
wherein determining the lumen cross-section includes determining a plane perpendicular to a guideline.

19. The computer program product of claim 15, comprising:
program code determining a distance between the center point and the updated center point; and
program code for determining a final center point after determining the distance between the center point and the updated center point.

20. The computer program product of claim 15, comprising:
program code for determining a plurality of centroid-based center points for a plurality of lumen cross-sections;
program code for determining a centerline for the lumen model using the plurality of centroid-based center points; and
program code for determining a plurality of branching region edges using the plurality of lumen cross-sections and the plurality of centroid-based center points.

21. A method for designing a stent for an airway, comprising:
determining a lumen cross-section of an airway lumen model;
determining a center point of the lumen cross-section;
determining a plurality of surface points of a surface of the lumen cross-section; and
determining an updated center point using a centroid of the plurality of surface points.

22. The method of claim 21, comprising determining a cross-section guideline of a lumen model, wherein determining the lumen cross-section includes determining a plane perpendicular to a guideline.

23. The method of claim 21, comprising:
determining a distance between the center point and the updated center point; and
determining a final center point after determining the distance between the center point and the updated center point.

24. The method of claim 21, comprising:
determining a plurality of centroid-based center points for a plurality of lumen cross-sections; and
determining a centerline for the airway lumen model using the plurality of centroid-based center points.

25. The method of claim 24, comprising:
determining a plurality of branching region edges using the plurality of lumen cross-sections and the plurality of centroid-based center points.
